(19) United States
(12) Patent Application Publication
(10) Pub. No.: US 2002/0025645 A1
(43) Pub. Date: Feb. 28, 2002

(54) METHOD FOR MANUFACTURING BURIED LAYER WITH LOW SHEET RESISTENCE AND STRUCTURE FORMED THEREBY

(76) Inventor: WEN-YING WEN, HSINCHU (TW)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 09/220,392

(22) Filed: Dec. 23, 1998

(51) Int. Cl. H01L 21/336

(52) U.S. Cl. 438/307; 438/301; 257/383

(57) ABSTRACT

The present invention provide a method for reducing the sheet resistance of the buried layer serving as the bit line or an interconnect of a semiconductor device. The method includes steps of providing the silicon substrate, doping the silicon substrate for forming an extrinsic silicon region, and forming a silicide layer on the extrinsic silicon region for obtaining a low-resistance buried layer.

### FIELD OF THE INVENTION

The present invention relates to a method for reducing the sheet resistance of a buried layer and the structure formed there by, and more particular to a method for reducing the sheet resistance of a buried layer by a salicide process and the structure formed thereby.

### BACKGROUND OF THE INVENTION

In the manufacturing of a memory array, a buried N⁺ layer is usually adopted as the bit line or an interconnect. For example, in a MOS (metal-insulator-semiconductor) process, phosphorus and arsenic can be implanted into the silicon substrate to form a buried N⁺ layer. The buried N⁺ layer serves as a bit line of the memory array. The memory array will be manufactured after the bit lines are formed. The adoption of the buried N⁺ layer as the bit line or the interconnect will reduce the cell size. Accordingly, the high integration is achieved and the cost is reduced.

FIG. 1 illustrates a conventional memory array circuit. The memory array circuit 1 includes the bit lines (or the common ground lines) 11 and the word line 12. FIG. 2 illustrates conventional buried layer structures 21 adopted as the bit lines (or the common ground lines) 11. The lines 22 are formed by polysilicon layers and serve as the word lines 12.

However, when the number of the memory cells are increased, the lengths of the bit lines which are formed by the buried layer structures 21 will also be increased. Thus, the resistance of the bit lines proportional to the lengths of the buried layer structures will seriously decrease the speed of the memory device's operation. Therefore, an improved buried layer structure, as illustrated in FIG. 3, is developed. FIG. 3 is a cross-sectional view of FIG. 2 along the A-A′ line. As shown in FIG. 3, a metal conducting layer 33 is formed above the bulk structure of the memory device. When the length of the buried layer 31, i.e. the resistance of the bit line, increases to a certain value, the operation speed will be significantly influenced. The contacts 34 are formed on the areas between the polysilicon lines 32 (as the areas labeled “A” illustrated in FIG. 2). Accordingly, the buried layer structure 31 is connected with the metal conducting layer 33 in parallel through the contacts 34, and the operation speed thus is maintained. However, as shown in FIG. 2, each of the contacts 34 occupies a portion having width W on the buried layer 21. The width W of the contacts will limit the scale-down of the elements. It is then attempted by the present invention to solve the above-mentioned problems.

### SUMMARY OF THE INVENTION

An object of the present invention is to provide a low-sheet resistance buried layer on a silicon substrate.

The other object of the present invention is to provide a method for reducing the buried layer on a silicon substrate without increasing the area of the device.

In this invention, an oxide layer formation, a spacer etching and a salicide module formation are added into a manufacturing process of a conventional memory device. The well and isolation formations are the same as those of the conventional process. A buried layer is formed. The steps for defining the buried layer and the formation of the buried layer's mask are the same as those in the conventional process. Phosphorus or arsenic is implanted to form the buried N⁺ junction. Then, a thin dielectric oxide layer is deposited, and a spacer etching is executed. This step can also be done before the implant step. The order of the steps depends on the requirement of the effective device channel length.

In the salicide module formation process, a titanium/titanium nitride layer is deposited, and a first rapid thermal processing is done. And then, the portion of the titanium/titanium nitride that doesn't react with the silicon substrate in the first rapid thermal processing is removed by a selective etching. The silicon nitride layer and the spacers serve as the hard mask of the process for forming the salicide film. The salicide film is completed by a second rapid thermal processing. The salicide film reduces the resistance of the buried layer structure, and thus maintains the operation speed while the length of the buried layer structure is increased to a relatively large value.

A dielectric oxide layer is then deposited by a method such as the high-density plasma chemical vapor deposition (HDPCVD) or plasma-enhanced vapor deposition (PECVD). An etching back or chemical mechanical polishing is done for planarization and protecting the salicide film. Then, the silicon nitride layers are removed.

The following steps (such as from the gate formation to the passivation formation) are the same as those in the conventional process.

The present invention may best be understood through the following description with reference to the accompanying drawings, in which:

### BRIEF DESCRIPTION OF THE DRAWINGS

FIG. 1 is a diagram illustrating a memory array;

FIG. 2 illustrates the buried layer serving as the bit line of a conventional memory array;

FIG. 3 illustrates a conventional structure for reducing the sheet resistance of a buried layer;

FIGS. 4(a)-4(f) illustrate a preferred embodiment of the process for manufacturing a low-resistance buried layer according to the present invention; and

FIG. 5 illustrates a procedure of another preferred embodiment of a process for manufacturing a low-resistance buried layer according to the present invention.

### DETAILED DESCRIPTION OF THE PREFERRED EMBODIMENTS

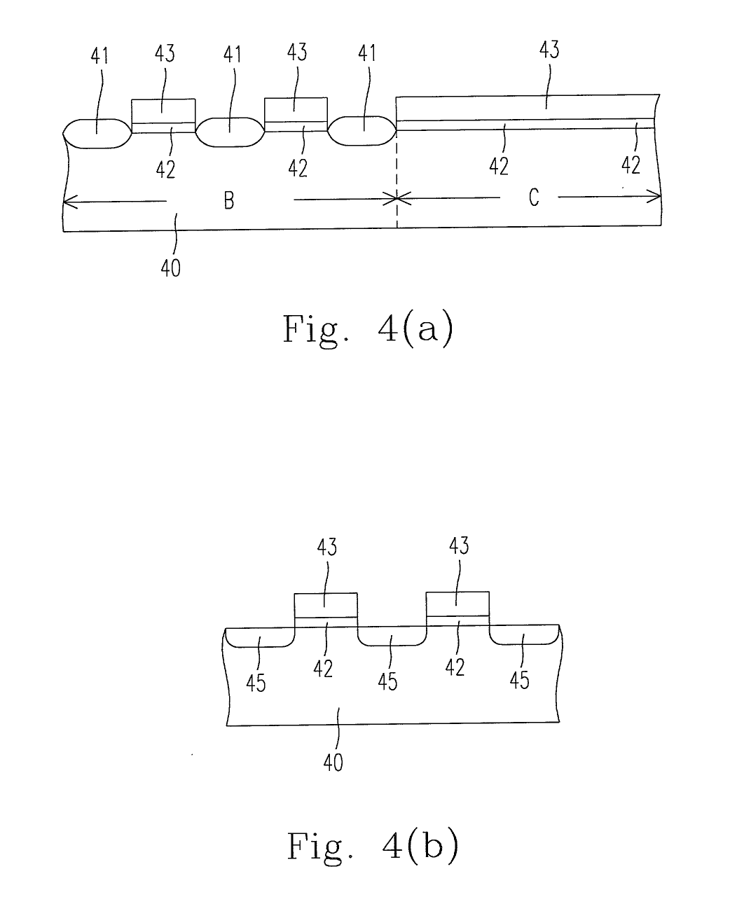

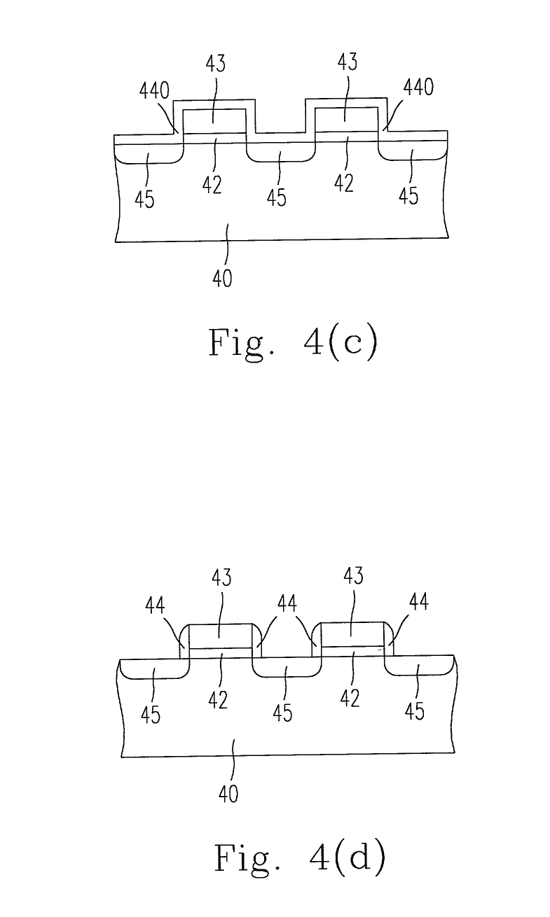

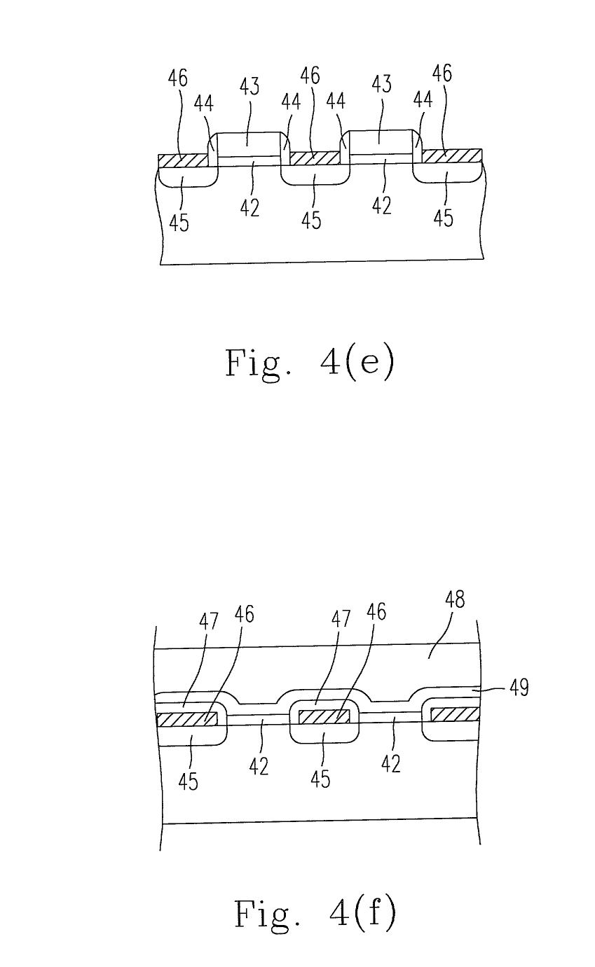

Basically, the method of the present invention can be applied on various memory devices manufacturing process such as process for manufacturing mask read-only memory (mask ROM), flash erasable programmable read-only memory (flash EPROM), e.t.c... A mask ROM manufacturing process is described for illustrating the method of the present invention. However, the scope of the present invention should not be limited in this embodiment. FIGS. 4(a)-4(f) illustrate the process for manufacturing the mask ROM. The process is a preferred embodiment of the method of the present invention. Referring to FIG. 4(a), the structure is constructed by the silicon substrate 40, the field oxide layer 41, the silicon dioxide layer 42 and the silicon nitride layer 43. In FIG. 4(a), the portion “B” illustrates a peripheral circuit, while the portion “C” is a memory array. The procedures for forming the well and the isolation are the same as those in the process for manufacturing a conventional mask ROM and will not be described here. The following description about FIGS. 4(b)-4(f) will focus on the manufacture of the memory array in the portion “C”, i.e., the formation of the structure related to the buried layer of the present invention.

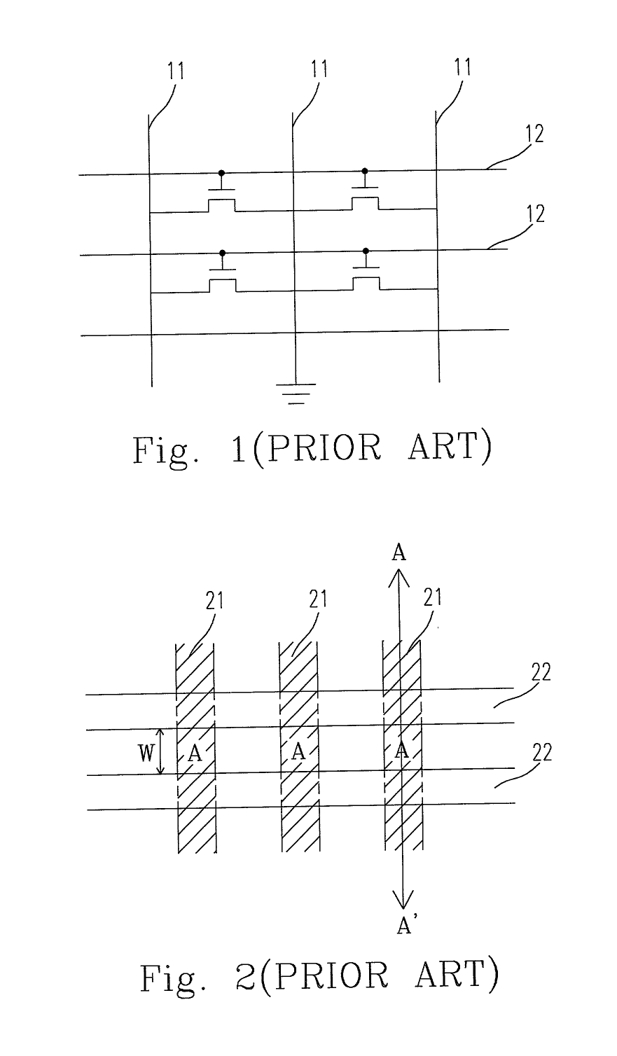

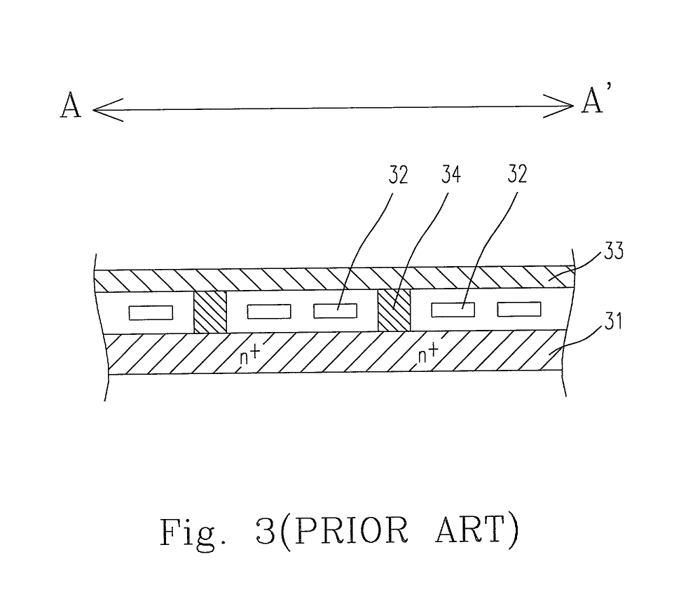

FIG. 4(b) illustrates a portion of the “C” part. As shown in FIG. 4(a), a silicon dioxide layer 42 and a silicon nitride layer 43 are formed above the silicon substrate 40. The silicon dioxide layer 42 and the silicon nitride layer 43 are etched according to a mask formed by a photolithography process. Accordingly, the areas 45 for forming the buried layer on the silicon substrate 40 are exposed. Then, as illustrated in FIG. 4(b), the silicon nitride 43 serves as the mask of a succeeding doping process. In such a process, phosphorus or arsenic is implanted into silicon substrate 40 so that the n type silicon regions 45 are formed. The extrinsic silicon regions (n type silicon regions) 45 are the same as the buried layers 21 and 31 shown in FIGS. 2 and 3, which serve as the bit lines or interconnects of the memory array.

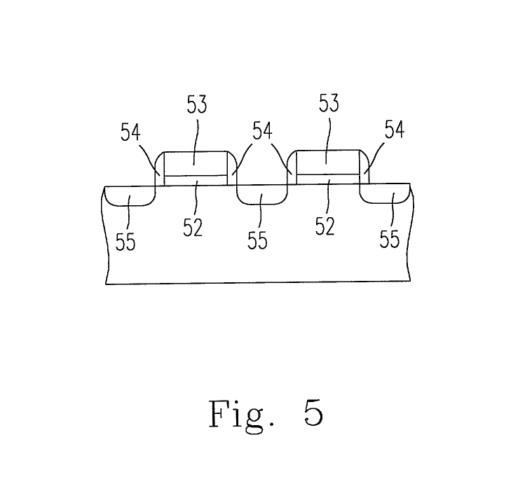

In FIGS. 4(c) and 4(d), the spacers 44 made of silicon dioxide are formed beside the sidewalls of the silicon dioxide layer 42 and the silicon nitride layer 43. The formation of the spacers 44 can also be done before the implant of the extrinsic silicon region 45, as indicated in FIG. 5. The order of the steps depends on the requirement of the effective device channel length. While forming the spacers 44, TEOS (tetra-ethyl-ortho-silicate) can be used as a reactant to deposit a thin silicon dioxide layer 440 on the substrate 40 by a low-pressure chemical vapor deposition (LPCVD). As shown in FIG. 4(c), the silicon dioxide layer 440 is deposited. The silicon dioxide layer 440 has a thickness of about 100Å to 1000Å. A spacer etching is then executed to obtain the spacers 44 as shown in FIG. 4(d). The formed buried layer 45 has a very high sheet resistance (which has a value of about 30 to 50 Ohm). Such a high sheet resistance will reduce the operation speed. The present invention applies a self-aligned silicide (salicide) process on the n type silicon region 45 to reduce its sheet resistance. Accordingly, the operation speed can be maintained without formation of contact holes on the surface of the device. The silicon nitride 43 and the spacers 44 serve as the mask of the salicide process.

A layer of metal titanium/titanium nitride (Ti/TiN) is deposited on the surface of the silicon substrate 40 shown in FIG. 4(d). A first rapid thermal processing (RTP) then undergoes under a nitride atmosphere and at a temperature of about 650° C. Accordingly, a portion of the deposited metal titanium reacts with the silicon on the surface of the n type silicon region 45, and thus a TiSiₓ layer 46 having a C49 phase is formed. Then a selective etching is executed for removing the non-reacted titanium/titanium nitride layer. Finally, a second rapid thermal processing is executed under a nitride atmosphere and at a temperature of about 825° C. Therefore, the C49-phase TiSiₓ layer is converted into a C54-phase TiSiₓ layer 46 that has an even lower resistance value. The TiSiₓ layer 46 formed by the above-mentioned self aligned process, as shown in FIG. 4(e), has a relatively low sheet resistance of about 3 to 5 Ohm.

After the TiSiₓ layer 46 is formed, an oxide layer 47 is deposited above the wafer by a high-density plasma chemical vapor deposition (HDPCVD) or a plasma-enhanced vapor deposition (PECVD). Furthermore, a planarization process is executed by using an etching back or a chemical mechanical polishing (CMP). Therefore, the silicide layer (TiSiₓ) 46 is protected by the spacers 44 and the oxide layer 47 to avoid the contamination that may take place in the following procedures such as a gate oxidation.

The silicon nitride layer 43 is then removed. The procedures for forming the remaining portions of the mask ROM are the same as those of the conventional process. The final product, as indicated in FIG. 4(f), has a polysilicon layer 49 and a passivation layer 48. It is noticeable that a high temperature is needed for forming the polysilicon layer 49. If the TiSiₓ layer 46 is not protected by the spacers 44 and the oxide layer 47, a short circuit may happen between the TiSiₓ layer 46 and the polysilicon layer 49. The low-resistance buried layer structure, constructed by the n type silicon region 45 and the self-aligned salicide (TiSiₓ) layer 46, will maintain the operation speed while the length of the buried layer structure is increased to a relatively large value. There is no need to form contact windows and conduct metal layers to reduce the value of resistance of the buried layer structure within such a length. Even if the bit line (i.e. the buried layer) exceeds such a length, the total number of the needed contact windows is still reduced. Accordingly, The area occupied by the contact windows is largely reduced as compared with the conventional method, and thus the problem of reducing the size of the device is solved. The method of the present invention can be applied to the manufacture of any semiconductor device having a buried layer structure.

While the invention has been described in terms of what are presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for forming a low-resistance buried layer on a silicon substrate of a semiconductor device, comprising steps of:
providing said silicon substrate;
doping said silicon substrate for forming an extrinsic silicon region; and
forming a silicide layer on said extrinsic silicon region for obtaining said low-resistance buried layer.

2. A method according to claim 1 wherein said semiconductor device includes a memory array, and said low-resistance buried layer is a bit line of said memory array.

3. A method according to claim 1 wherein said low-resistance buried layer is an interconnect of said semiconductor device.

4. A method according to claim 1 wherein said step for doping said silicon substrate includes steps of:
forming a silicon nitride layer over said silicon substrate;
etching said silicon nitride layer to expose a portion of said silicon substrate for forming said buried layer; and
doping said portion of said silicon substrate to obtain said extrinsic silicon region.

5. A method according to claim 4 wherein said step for forming said silicide layer on said extrinsic silicon region includes steps of:
forming a spacer on a sidewall of said silicon nitride layer; and
executing a salicide process by using said silicon nitride layer and said spacer as a mask to obtain said silicide layer.

6. A method according to claim 5 wherein said step for forming said spacer on said sidewall of said silicon nitride layer includes steps of:
forming an dielectric layer over said silicon nitride layer; and
executing a spacer etching for obtaining said spacers.

7. A method according to claim 6 wherein said dielectric layer is a silicon dioxide layer, and said silicon dioxide layer is made from tetra-ethyl-ortho-silicate (TEOS).

8. A method according to claim 5 wherein said salicide process includes steps of:
depositing a titanium/titanium nitride (Ti/TiN) layer on said silicon substrate;
executing a first rapid thermal processing to form a titanium silicide (TiSiₓ) layer on the junction of said silicon substrate and said titanium/titanium nitride layer; and
executing a selective etching for removing said titanium/titanium nitride layer and remaining said titanium silicide layer on said silicon substrate.

9. A method according to claim 8 wherein said first rapid thermal processing is executed at a temperature of about 650° C. and under a nitride atmosphere.

10. A method according to claim 8 wherein said step salicide process further includes steps of:
executing a second rapid thermal processing for reducing the resistance of said titanium silicide layer.

12. A method according to claim 11 wherein said second rapid thermal processing is executed at a temperature of about 825° C. and under a nitride atmosphere.

13. A method according to claim 1, further comprising a step of:
forming an oxide layer over said silicide layer.

14. A method according to claim 13, further comprising a step of:
forming a polysilicon layer above said oxide layer and said silicide layer, wherein said silicide layer is protected by said oxide layer during forming said polysilicon layer.

15. A method according to claim 14, further comprising a step of forming a spacer on a sidewall of said silicide layer beforing forming said polysilicon layer, wherein said sidewall of said silicide layer is protected by said spacer during forming said polysilicon layer.

16. A method according to claim 13, further comprising a step of: executing a planarization process on said oxide layer.

17. A low-resistance buried layer structure according to claim 1, comprising:
said silicon substrate;
said extrinsic silicon region formed by doping a dopant into a portion of said silicon substrate wherein said portion of said silicon substrate is used for forming said buried layer; and
said silicide layer formed on a surface of said extrinsic silicon region.

18. A low-resistance buried layer structure according to claim 17 wherein said buried layer structure is one of a bit line and an interconnect of said semiconductor device.

19. A low-resistance buried layer structure according to claim 17 wherein said silicide layer is a titanium silicide (TiSiₓ) layer.

20. A low-resistance buried layer structure according to claim 19 wherein said titanium silicide layer is formed by a first rapid thermal processing to have a C49 phase, and then processed by a second rapid thermal processing to have a C54 phase.

21. A low-resistance buried layer structure according to claim 17 wherein said dopant is one of phosphorus and arsenic.

22. A low-resistance buried layer structure according to claim 17, further comprising an oxide layer covering said silicide layer.

23. A low-resistance buried layer structure according to claim 22, further comprising a spacer covering a sidewall of said silicide layer.

24. A low-resistance buried layer structure according to claim 23, further comprising a polysilicon layer covering said oxide layer and said spacer, wherein said silicide layer is protected by said oxide layer and said spacer during forming said polysilicon layer.
